(19) United States
(12) Patent Application Publication
(10) Pub. No.: US 2007/0010073 A1
(43) Pub. Date: Jan. 11, 2007

(54) Method of forming a MOS device having a strained channel region

(76) Inventors: Chien-Hao Chen, Chuangwei Township (TW); Chun-Feng Nieh, Baoshan Township (TW); Tze-Liang Lee, Hsinchu (TW); Shih-Chang Chen, Hsin-Chu (TW); Mong Song Liang, Hsin-Chu (TW)

Correspondence Address: SLATER & MATSIL, L.L.P., 17950 PRESTON ROAD, SUITE 1000, DALLAS, TX, 75252, US

(21) Appl. No.: 11/175,563

(22) Filed: Jul. 6, 2005

(51) Int. Cl. H01L 21/20; H01L 21/4763

(52) U.S. Cl. 438/486; 438/648; 257/E29.266; 257/E29.156

(57) ABSTRACT

A method of forming a semiconductor device comprising providing a substrate comprising a first device region, implanting a source/drain region in the first device region, forming a strained capping layer on the source/drain region, super annealing and crystallizing the source/drain region, and removing substantially all of the strained capping layer is provided. The method further includes pre-amorphizing the source/drain region before the super annealing. The strained capping layer may further be formed on a pre-amorphized gate electrode, and the gate electrode is super annealed. The strain is generated and preserved after the removal of the strained capping layer.

### TECHNICAL FIELD

This invention relates generally to metal-oxide-semiconductor (MOS) devices, and more particularly to MOS devices with strained channel regions and processes for forming the same.

### BACKGROUND

The scaling of VLSI circuits is a constant effort. With circuits becoming smaller and faster, device driving current improvement is becoming more important. Device current is closely related to gate length, gate capacitance, and carrier mobility. Shortening poly-gate length, increasing gate capacitance, and increasing carrier mobility can improve the device current performance. Gate length reduction is an on-going effort to shrink circuit size. Increased gate capacitance has been achieved by efforts such as reducing the thickness of the gate dielectric, increasing the gate dielectric constant, and the like. In order to further improve device current, the enhancement of carrier mobility has also been explored.

Among efforts made to enhance carrier mobility, forming a strained silicon channel is a known practice. Strain, sometimes referred to as stress, can enhance bulk electron and hole mobility. The performance of a MOS device can be enhanced through a strained-surface channel. This technique allows performance improvement at a constant gate length, without adding complexity to circuit fabrication or design.

When silicon is placed under strain, the in-plane, room temperature electron mobility is dramatically increased. One way to develop strain is by using a graded SiGe epitaxy layer as a substrate on which a layer of relaxed SiGe is formed. A layer of silicon is formed on the relaxed SiGe layer. MOS devices are then formed on the silicon layer, which has inherent strain. Since the lattice constant of SiGe is larger than that of Si, the Si film is under biaxial tension and thus the carriers exhibit strain-enhanced mobility.

Strain in a device may have components in three directions: parallel to the MOS device channel length, parallel to the device channel width, and perpendicular to the channel plane. The strains parallel to the device channel length and width are called in-plane strains. Research has revealed that a bi-axial, in-plane tensile strain field can improve NMOS performance, and compressive strain parallel to channel length direction can improve PMOS device performance.

Strain can also be applied by forming a strained capping layer, such as a contact etch stop (CES) layer, on a MOS device. When a strained capping layer is deposited, due to the lattice spacing mismatch between the capping layer and underlying layer, an in-plane stress develops to match the lattice spacing. FIG. 1 illustrates a conventional MOS device having a strained channel region. Strained capping layers, such as spacers 9 and CES layer 14, introduce a strain in source/drain regions 12 (including LDD regions 15), and a strain is generated in channel region 11. Therefore, the carrier mobility in the channel region 11 is improved.

The conventional methods of creating strain cause a dilemma. The strain of the channel region is affected by the thickness of the strained capping layer, wherein a thicker capping layer applies a greater strain. However, the thickness of the strained capping layer is limited due to the difficulties associated with subsequent gap filling processes required by the thick capping layer. This in turn limits the strain that can be applied by the capping layer. If the strained capping layer is removed, the strain applied by it will typically disappear.

What is needed, then, is a novel method for applying a strain to the channel region of the MOS device.

### SUMMARY OF THE INVENTION

The preferred embodiments of the present invention provide an improved method of forming a MOS device having strained channel regions.

In accordance with one aspect of the present invention, the method includes providing a substrate comprising a first device region, implanting a source/drain region of a first MOS device in the first device region, forming a strained capping layer on the source/drain region, super annealing and crystallizing the source/drain region, and removing substantially all of the strained capping layer. The method further comprises pre-amorphizing the source/drain region before super annealing. A strain is generated and preserved in the source/drain region.

In accordance with another aspect of the present invention, the method further includes forming a polysilicon gate electrode layer in the first device region, patterning the gate electrode layer to form a gate electrode, pre-amorphizing at least a top portion of the gate electrode, forming a strained capping layer on the gate electrode, and super annealing and crystallizing the gate electrode. In the preferred embodiment, the gate electrode is pre-amorphized and super annealed simultaneously as the source/drain region is pre-amorphized and super annealed, respectively. In other embodiments, the steps of pre-amorphizing the gate electrode, forming the strained capping layer, super annealing, and removing the strained capping layer can be performed before or after the formation of the gate spacers.

In accordance with yet another aspect of the present invention, the method further includes forming a second MOS device in a second device region, wherein the second MOS device is masked when the first device is pre-amorphized and super annealed.

In accordance with yet another aspect of the present invention, an additional strained capping layer, which has a different inherent strain from the strained capping layer, is formed on the pre-amorphized source/drain and gate electrode of the second MOS device. After the removal of the strained capping layer and the additional strained capping layer, the channel regions of the first and second MOS devices have different strains.

The preferred embodiments of the present invention have the advantageous feature of improving the strain in a MOS device without increasing the thickness of the contact etch stop layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional MOS device having a strained channel region, wherein a contact etch stop layer applies a strain;

FIGS. 2 through 9 are cross-sectional views of intermediate stages in the manufacture of a MOS transistor embodiment; and

FIGS. 10 through 12 illustrate variations of the preferred embodiment.

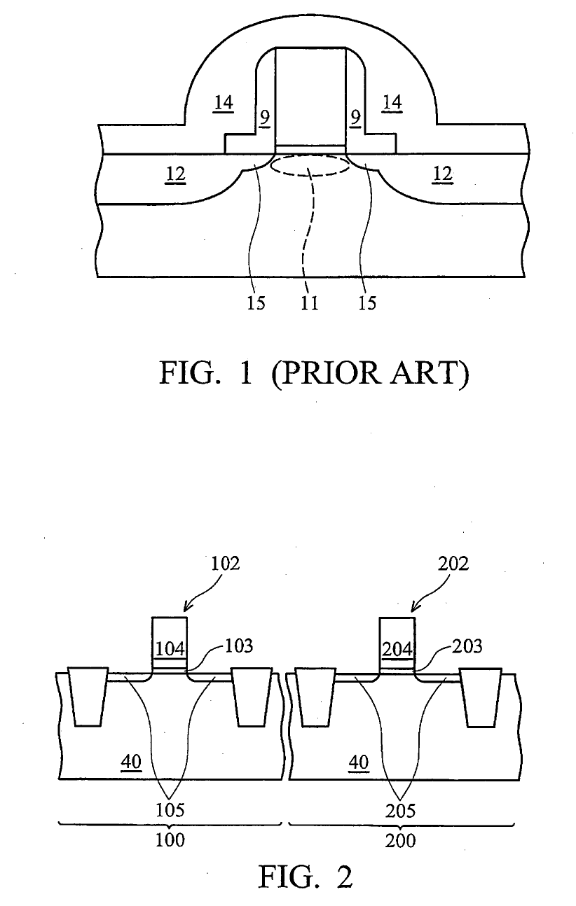

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

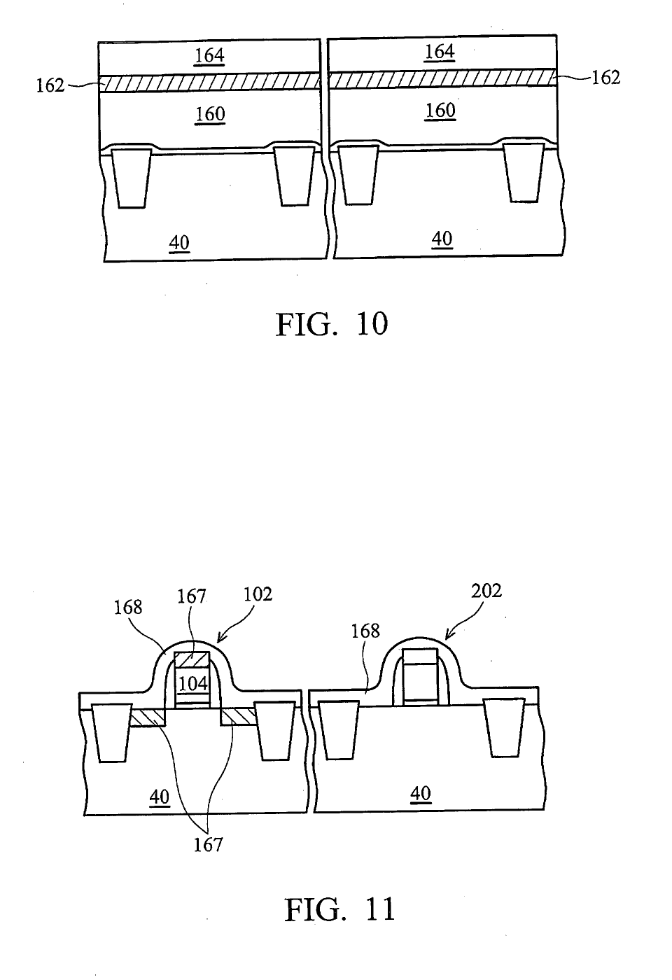

The preferred embodiments of the present invention are illustrated in FIGS. 2 through 9. Variations of the preferred embodiments are then discussed with reference to FIGS. 10 through 12. Throughout the various views and illustrative embodiments of the present invention, like reference numbers are used to designate like elements.

Referring to FIG. 2, a substrate 40 is provided. The substrate 40 can be formed of common substrate materials such as silicon, SiGe, strained silicon on SiGe, silicon on insulator (SOI), silicon germanium on insulator (SGOI), germanium on insulator (GOI), and the like. The substrate 40 preferably includes device regions 100 and 200, which are used for forming different logic devices. In one embodiment, one of the regions 100 and 200 is used for a PMOS transistor, and the other is used for an NMOS transistor. In another embodiment, one of the regions 100 and 200 is a core region comprising a core device, and the other is a peripheral region comprising an I/O device.

A first gate structure 102 comprising a gate dielectric 103 and a gate electrode 104 and a second gate structure 202 comprising a gate dielectric 203 and a gate electrode 204 are formed in the regions 100 and 200, respectively. As is well known in the art, in order to form the gate structures, a gate dielectric layer is formed on the substrate 40 and a gate electrode layer is formed on the gate dielectric layer. In the preferred embodiment, the gate electrode layer comprises polysilicon. In other embodiments, other conductive materials such as metals or metal silicides can be used. The gate dielectric layer and gate electrode layer are then patterned to form the gate dielectrics 103 and 203 and the gate electrodes 104 and 204 in regions 100 and 200, respectively. Lightly doped drain/source (LDD) regions 105 and 205 are preferably formed by implanting appropriate impurities.

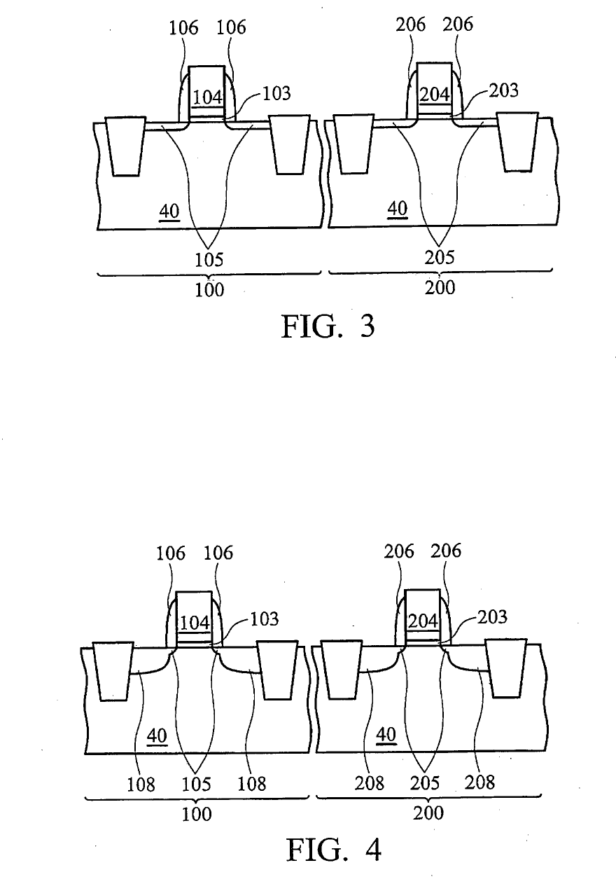

FIG. 3 illustrates the formation of gate spacers 106 and 206. To form the gate spacers, a spacer layer is typically blanket deposited on the previously formed structure. The spacer layer preferably comprises SiN, oxynitride, SiC, SiON, oxide, and the like and is preferably formed by commonly used methods such as chemical vapor deposition (CVD), plasma enhanced CVS, sputter, and the like. The spacers 106 and 206 are then patterned, preferably by anisotropically etching and removing the spacer layer from the horizontal surfaces.

FIG. 4 illustrates the formation of the source/drain regions 108 and 208. The source/drain regions 108 and 208 may be recessed in or elevated above the substrate 40 (using, e.g., epitaxially grown regions), and the subsequently formed strain-inducing layer will also be recessed or elevated accordingly. In the preferred embodiment, the source/drain regions 108 and 208 are formed by implanting impurities into the substrate 40. The respective spacers 106 and 206 are used as masks so that the edges of the source/drain regions 108 and 208 are substantially aligned with the respective spacers. Gate electrodes 104 and 204 are preferably implanted to reduce sheet resistance. The implantation causes the crystallized structure of the source/drain regions 108 and 208 to be destroyed, and an amorphous structure to be formed.

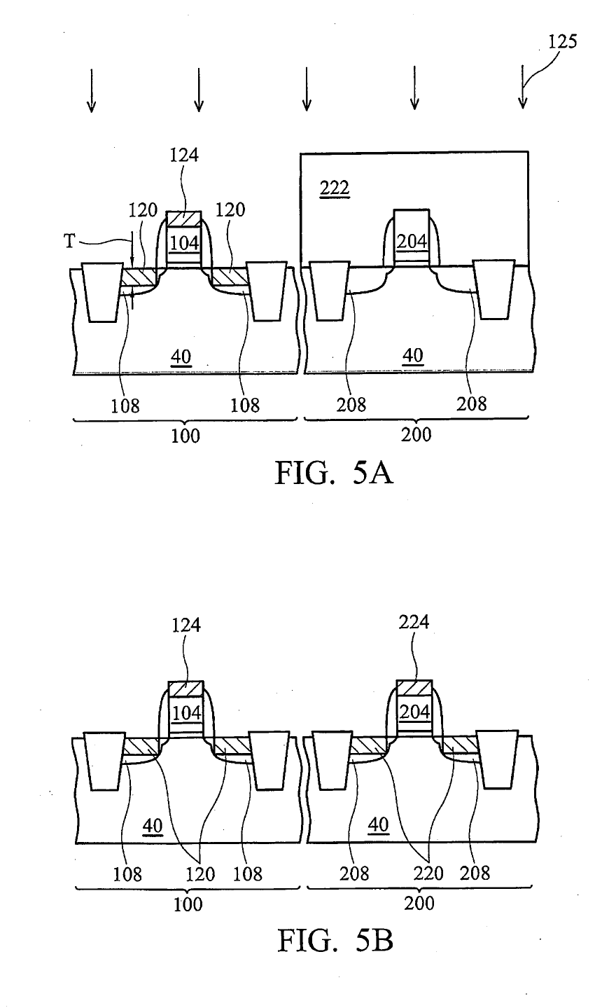

A masking layer 222 is formed to cover region 200, as shown in FIG. 5A. In the preferred embodiment, the masking layer 222 is preferably a photo resist layer. In alternative embodiments, the masking layer 222 includes layers such as a photo resist, an anti-reflective coating (ARC), a hard mask, and combinations thereof.

A pre-amorphization implantation (PAI), as symbolized by arrows 125, is performed. In the preferred embodiment, silicon or germanium is implanted. In other embodiments, inert gases, such as neon, argon, xenon, and radon, are used. The pre-amorphization implantation destroys the lattice structure of the substrate 40 and prevents subsequently doped impurities from channeling through spaces between the crystal lattice structure and reaching depths greater than desired. At a minimum, exposed top portions 120 of the (single crystalline) substrate 40 and a top portion 124 of the (polysilicon) gate electrode 104 are turned into an amorphous state as a result of the PAI. Preferably, the portions 120 have a depth T of greater than about 20nm. The masking layer 222 is then removed.

In alternative embodiments, as shown in FIG. 5B, the masking layer 222 is not formed, and the exposed top portions of the substrate 40 and a top portion of the respective gate electrode 204 in the region 200 are also pre-amorphized, forming amorphous regions 220 and 224, respectively.

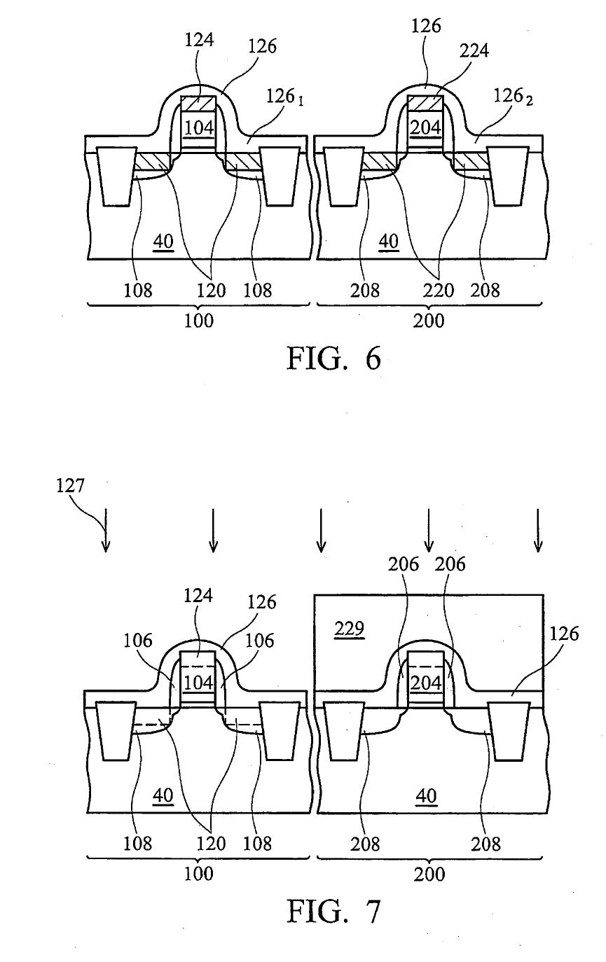

FIG. 6 illustrates the formation of a strained capping layer 126. Depending on the type of MOS device to be formed, appropriate materials are selected to apply either compressive or tensile strain to the channel region of the device. Preferably, the materials include commonly used materials such as SiN, oxynitride, oxide, SiGe, SiC, SiON, and combinations thereof. A buffer layer (not shown) may be formed immediately on the substrate 40. The buffer layer is preferably an oxide film acting as an etch stop layer when removing the applied strain layer (such as SiN). For example, the oxide buffer layer protects the Si substrate from attack by H₃PO₄ during removal of the nitride strained layer.

In the preferred embodiment, the strained capping layer 126 has a single layer. In other embodiments, it may have a laminated structure with multiple layers. In yet other embodiments, the strained capping layer 126 includes a first portion 126, in region 100, and a second portion 1262 in region 200. The first and second portions 126, and 1262 are preferably formed of different materials and/or by different forming processes, so that the inherent strains are different.

Referring to FIG. 7, a super anneal, which is symbolized by arrows 127, is then performed, preferably by exposing the substrate 40 to a high-energy source, such as a laser or flash, for a short duration. The features on the substrate 40 are annealed due to the rapid increase of the temperature. Preferably, the wavelength of the high-energy source is between about 1 mm and about 1 mm. By adjusting the wavelength, the substrate can be annealed to a desired depth. The longer the wavelength is, the greater the annealing depth will be. The annealing depth is preferably greater than about 200 nm, and is preferably greater than the thickness of the pre-amorphized portions 124 and 224. The preferred anneal duration is between about one pico-second to about one second. The anneal temperature is preferably higher than about 1000° C., which can be achieved by adjusting the energy level of the high-energy source. In alternative embodiments, the super anneal includes a flash anneal.

A masking layer 229 may optionally be formed to mask region 200, so that only region 100 is super annealed. The energy of the super anneal is absorbed (and/or reflected) by the masking layer 229, and region 200 is protected from super annealing.

The super anneal has the function of modulating the strain in the strained capping layer 126. Typically, the strain value in the strained capping layer 126 tends to change toward the tensile side after being super annealed. A correlation exists between the increase of the strain value and the energy of the super anneal, wherein the higher the energy is, the greater the increase will be. Therefore, the strain values in the strained capping layer 126 can be adjusted by subjecting the devices to different energy levels.

The super anneal re-crystallizes the pre-amorphized materials. When the pre- amorphized portions 120 and 124 re-crystallize, the surrounding features affect their lattice structures. For example, the lattice structure of the pre-amorphized portion 120 is affected by the strained capping layer 126, the spacers 106, and other parts of the substrate 40.

In the embodiments wherein the strained capping layer 126 comprises portions 126, and 1262, which have different inherent strains, after the strained capping layer 126 is removed, the strains in the source/drain regions 108 and 208 and the strains in the gate electrodes 104 and 204 will be different. The resulting strains in the channel regions of the MOS devices in regions 100 and 200 are thus different.

The preferred embodiments of the present invention may further include additional anneal approaches, such as a furnace anneal, a rapid thermal anneal (RTA), a spike anneal, and the like. The additional anneal approaches further crystallize the pre-amorphized portions 120 and 124.

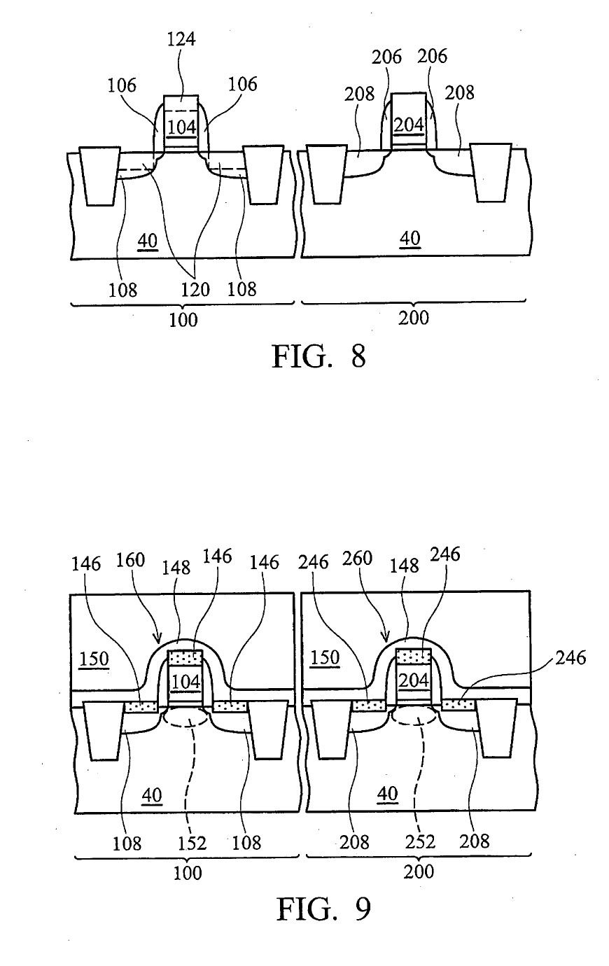

The strained capping layer 126 is then removed, as shown in FIG. 8, preferably by dry etch or wet etch. Since the pre-amorphized portions 120 and 124 are re-crystallized, the inherent strains in the pre-amorphized portions 120 and 124 are “memorized,” at least partially, and thus the strain applied to the channel region is also at least partially maintained. A possible reason that the strain is maintained is that the strains in the portions 120 and 124 are affected by the unremoved environment, such as all of the substrate 40, except the portions 120, which are not removed along with the strained capping layer 126.

In the preferred embodiment, the strained capping layer 126 is removed substantially completely. In other embodiments, small portions of the strained capping layer 126 may be left un-removed. For example, the remaining portions of the strained capping layer 126 can be used as a silicide protective layer, which may isolate certain portions of the silicon substrate 40 from subsequent silicide processes.

FIG. 9 illustrates the structure after the formation of silicide regions 146 and 246, a contact etch stop layer (CESL) 148, and an inter-layer dielectric (ILD) layer 150. As is known in the art, silicide regions 146 and 246 may be formed by salicide processes on the respective source/drain regions 108 and 208. To form a silicide layer, a metal layer is preferably formed by first depositing a thin layer of metal, such as cobalt, nickel, titanium, or the like, over the device. The device is then annealed to form a silicide between the deposited metal and the underlying exposed silicon regions. Un-reacted metal is removed.

In the preferred embodiment, the CESL 148 is blanket deposited using a material that provides a desirable strain to the channel region of the MOS device in region 100. Preferably, the CESL 148 comprises SiN, oxynitride, oxide, and the like. Next, the ILD layer 150 is deposited over the surface of the CESL 148.

In the previously discussed embodiments, different strains can be applied to the channel regions of the different MOS devices. For example, a first MOS device 160 is formed in region 100, and a second MOS device 260 is formed in region 200. The CESL 148 provides a first strain to the channel region 252 of the second MOS device 260. By pre-amorphizing and super annealing the polysilicon region 104 and the source/drain region 108, a second strain is generated and preserved in the channel region 152 of the first MOS device 160.

Strains may be generated and memorized at different stages in the fabrication processes of the preferred embodiments. FIG. 10 illustrates an embodiment for generating strain after polysilicon deposition and before its patterning. After forming a polysilicon gate electrode layer 160 over the substrate 40, a pre-amorphization is performed, and at least a top amorphous layer 162 is formed. A strained capping layer 164 is formed on the amorphous layer 162. A super anneal is then performed to crystallize the amorphous layer 162. After the strained layer 164 is removed, the top portion 162 of the gate electrode layer 160 has a preserved strain, and the strain is maintained after the gate electrode layer 160 is patterned to form gate electrodes.

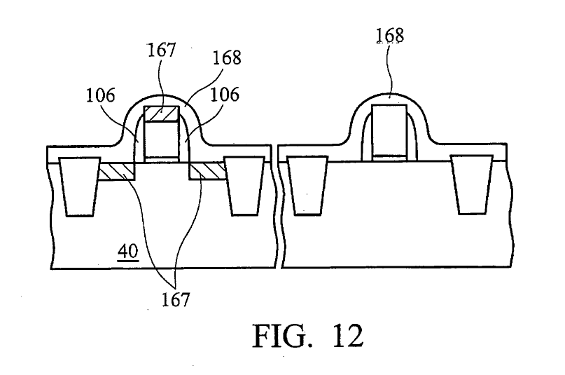

Further variations of the preferred embodiments of the present invention are illustrated in FIGS. 11 and 12. Referring to FIG. 11, after the gate stack 102 is patterned but before the formation of the spacers, the strain is generated by pre-amorphizing at least the top layer 167 of the gate electrode 104 and regions where source/drain regions will be formed, applying a strained layer 168, and super annealing the top layer 167. A further variation of the preferred embodiments is shown in FIG. 12, wherein the strain is generated and preserved after the formation of the spacers 106. In both embodiments, the crystallization may include an additional annealing process. The strained capping layer 168 is then removed.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method of forming a semiconductor structure, the method comprising:
providing a substrate;
forming a gate electrode over the substrate;
forming a source/drain region in the substrate;
forming an amorphous region in at least a top portion of at least one of the gate electrode and the source/drain region;
forming a strained capping layer over and contacting the amorphous region;
super annealing and crystallizing the amorphous region; and
removing substantially all of the strained capping layer.

2. The method of claim 1 wherein the amorphous region is formed in the source/drain region.

3. The method of claim 2 wherein the step of forming the source/drain region is performed by an implantation process and wherein the implantation process forms the amorphous region.

4. The method of claim. 2 wherein forming the amorphous region comprises a pre-amorphization implantation.

5. The method of claim 1 wherein the gate electrode comprises silicon and wherein the amorphous region is in the gate electrode.

6. The method of claim 1 further comprising an additional annealing step before the step of removing the strained capping layer.

7. The method of claim 1 further comprising:
forming a gate spacer along a sidewall of the gate electrode;
forming a silicide region on the source/drain region;
forming a contact etch stop layer over the source/drain region and the gate electrode; and
forming an inter-layer dielectric law over the contact etch stop layer.

8. A method of forming a semiconductor device, the method comprising:
providing a substrate comprising a first device region;
implanting a source/drain region in the first device region;
forming a strained capping layer over and contacting the source/drain region;
super annealing and crystallizing the source/drain region; and
removing substantially all of the strained capping layer.

9. The method of claim 8 wherein the super annealing is performed by exposing the substrate to a high-energy source.

10. The method of claim 8 wherein the super annealing has a duration of between about one nano-second and about one second.

11. The method of claim 8 further comprising pre-amorphizing at least a top portion of the source/drain region.

12. The method of claim 8 further comprising an additional annealing step before removing the strained capping layer.

13. The method of claim 8 further comprising:
forming a polysilicon gate electrode layer in the first device region;
pre-amorphizing at least a top portion of the gate electrode layer;
forming the strained capping layer on the gate electrode layer;
super annealing and crystallizing the gate electrode layer; and
patterning the gate electrode layer to form a gate electrode after the step of removing the strained capping layer.

14. The method of claim 8 further comprising:
forming a polysilicon gate electrode layer in the first device region;
patterning the gate electrode layer to form a gate electrode;
pre-amorphizing at least a top portion of the gate electrode;
forming the strained capping layer on the gate electrode;
super annealing and crystallizing the gate electrode before the step of removing the strained capping layer.

15. The method of claim 14 further comprising forming a gate spacer along a side edge of the gate electrode after the step of removing the strained capping layer.

16. The method of claim 14 further comprising forming a gate spacer along a side edge of the gate electrode before the step of forming the strained capping layer.

17. The method of claim 8 wherein the substrate further comprises a second device region, and wherein the second device region is masked when the steps of implanting the source/drain region, super annealing and crystallizing are performed.

18. A method of forming a semiconductor structure, the method comprising:
providing a substrate having a first and a second device region;
forming a first gate dielectric on the substrate in the first device region, and a first gate electrode on the first gate dielectric;
forming a second gate dielectric on the substrate in the second device region, and a second gate electrode on the second gate dielectric;
forming a first source/drain region in the first device region;
forming a second source/drain region in the second device region;
pre-amorphizing the first gate electrode and the first source/drain region;
forming a first strained capping layer over and contacting the first gate electrode and the first source/drain region;
super annealing and crystallizing the first gate electrode and the first source/drain region; and
removing the first strained capping layer.

19. The method of claim 18 further comprising masking the second device region before the step of super annealing and crystallizing the first gate electrode and the first source/drain region.

20. The method of claim 18 further comprising:
pre-amorphizing the second gate electrode and the second source/drain region;
forming a second strained capping layer on the second gate electrode and the second source/drain region, wherein the first and second strained capping layers have different strains;
super annealing and crystallizing the second gate electrode and the second source/drain region; and
removing the second strained capping layer.
